(19) United States
(12) Patent Application Publication
(10) Pub. No.: US 2026/0150180 A1
(43) Pub. Date: May 28, 2026

(54) ELECTRICAL COMPONENT THERMAL MANAGEMENT ASSEMBLY FOR SPACE APPLICATIONS

(71) Applicant: Raytheon Company, Arlington, VA (US)

(72) Inventors: Andrew J. Bristol, LOS ANGELES, CA (US); Paola V. Lopez, Santa Fe Springs, CA (US); Keith M. Regan, Torrance, CA (US); Rosalio S. Vidaurri, Los Angeles, CA (US); Kevin A. Miyamoto, Camarillo, CA (US); Jonte L. Robertson, Los Angeles, CA (US); Keith R. Burrell, Rancho Palos Verdes, CA (US); Eduardo Arana, Redondo Beach, CA (US); Darryl T. Kobayashi, Torrance, CA (US); Sung H. Lee, Valencla, CA (US)

(21) Appl. No.: 18/957,163

(22) Filed: Nov. 22, 2024

(51) Int. Cl. H05K 1/02; B64G 1/22

(52) U.S. Cl. CPC H05K 1/0204; B64G 1/22; H05K 2201/066

(57) ABSTRACT

An assembly for enhancing heat conduction for a component is provided. The assembly has a printed wiring board where the component is on the printed wiring board. The assembly has a first thermal interface material (TIM) and a heat sink. The heat sink has first and second sides and is on the first TIM at the heat sink first side and opposite the component. The first TIM thermally contacts both the component and the heat sink. The assembly has a cover on the heat sink second side. The cover defines a plurality of cooling fins having a cooling fin pattern. The heat sink includes a plurality of cooling fin recesses the define a cooling fin recess pattern complementary to the cooling fin pattern. A second TIM is within the cooling fin recesses and contacts the heat sink and the cover via the cooling fins and the cooling fin recesses.

### TECHNICAL FIELD

Examples relate to an assembly for an electrical component for spacecraft applications and more specifically to an assembly that provides thermal management for an electrical component of an assembly for spacecraft applications.

### BACKGROUND

Spacecraft require electronic components in order to properly function. Electronic components can be mounted on printed wiring boards disposed within the spacecraft. The temperature can be affected by the operation of the electrical components. Furthermore, thermal cycles, shock, and vibration can overstress part interfaces intended for heat transfer.

Since outer space is a vacuous environment, heat dissipation is accomplished through conduction where a thermal interface material (TIM) contact can be used to create a thermal path between the electronic components and the printed wiring boards and a metallic cover. However, during launch and while in orbit, the spacecraft can be subject to dynamic forces that can cause shock and vibration at the printed wiring boards and the electronic components. The shock and vibration along with thermal cycling that occurs can cause TIM contacts to migrate. Migration of TIM contacts can cause a break in the thermal path. By virtue of a break in the thermal path, this can lead to overheating of electronic components, which can lead to premature failure, thereby jeopardizing the mission of the spacecraft.

### BRIEF DESCRIPTION OF DRAWINGS

FIG. 1 illustrates a spacecraft on which examples described herein may be used.

FIGS. 2A-2C show an assembly for providing heat conduction for an electrical component of the spacecraft of FIG. 1.

FIG. 3 illustrates a cover of the assembly of FIG. 2.

FIG. 4 shows a gasket within a trough of a heat sink of the assembly of FIG. 2.

FIG. 5 is an exploded cross-sectional view showing the heat sink of FIG. 4 interfacing with the cover of FIG. 3.

### DETAILED DESCRIPTION

The following description and the drawings sufficiently illustrate teachings to enable those skilled in the art to practice them. Other embodiments may incorporate structural, logical, electrical, process, and other changes. Portions and features of some examples may be included in, or substituted for, those of other examples. Teachings set forth in the claims encompass all available equivalents of those claims.

Examples relate to an assembly that provides heat conduction for an electronic component for a spacecraft. The assembly can include a cover having a plurality of cooling fins along with a heat sink having a plurality of cooling fin recesses. The cooling fin recesses can have a configuration that is complementary to a configuration of the cooling fins such that the cooling fin recesses can receive the cooling fins. Furthermore, a TIM can be disposed within each cooling fin recess and contact a surface of a cooling fin disposed within the cooling fin recess thereby conducting heat from the heat sink to the cooling fin.

The TIM can be formed in order to minimize migration along with cracking. For example, the TIM can be moldable to fit within a top side of cooling fins. Thus, a thermal path created between the each of the cooling fin recesses and the cooling fins can be maintained when a spacecraft is subjected to various dynamic forces as noted above.

The heat sink can have a top surface along with a bottom surface that is opposite the heat sink top surface. The heat sink top surface can include the cooling fin recesses. An electrical component can be disposed at the heat sink bottom surface where an additional TIM can be disposed at the heat sink bottom surface between the heat sink and the electrical component. The additional TIM can be in thermal contact with both the heat sink bottom surface and the electrical component. Therefore, the additional TIM can form a thermal path between the electrical component and the heat sink. The thermal path created by the additional TIM can conduct heat away from the electrical component and to the heat sink. The thermal path created by the TIM disposed within each of the cooling fin recesses can conduct the heat from the electrical component to the cover.

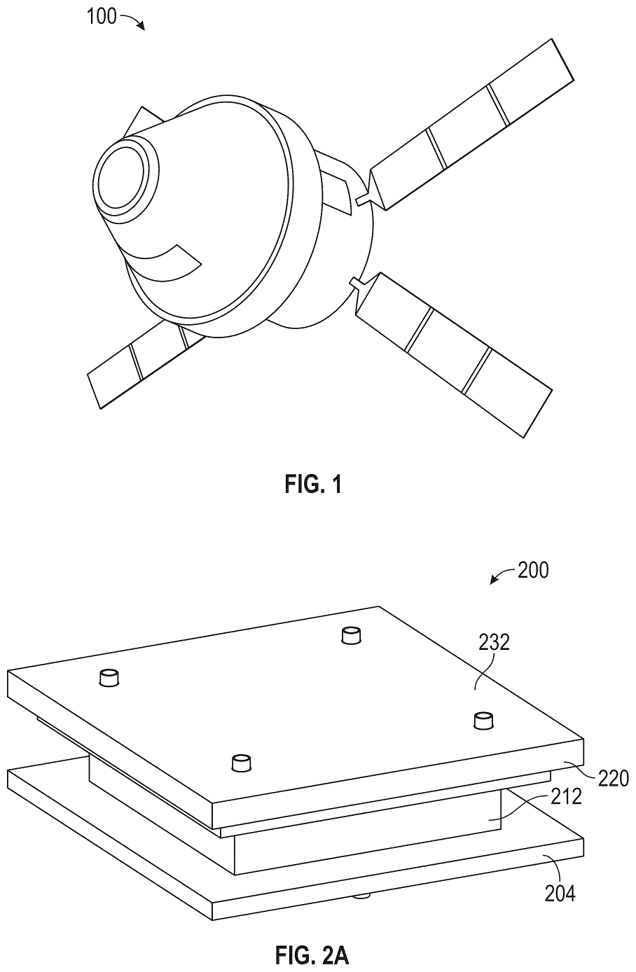

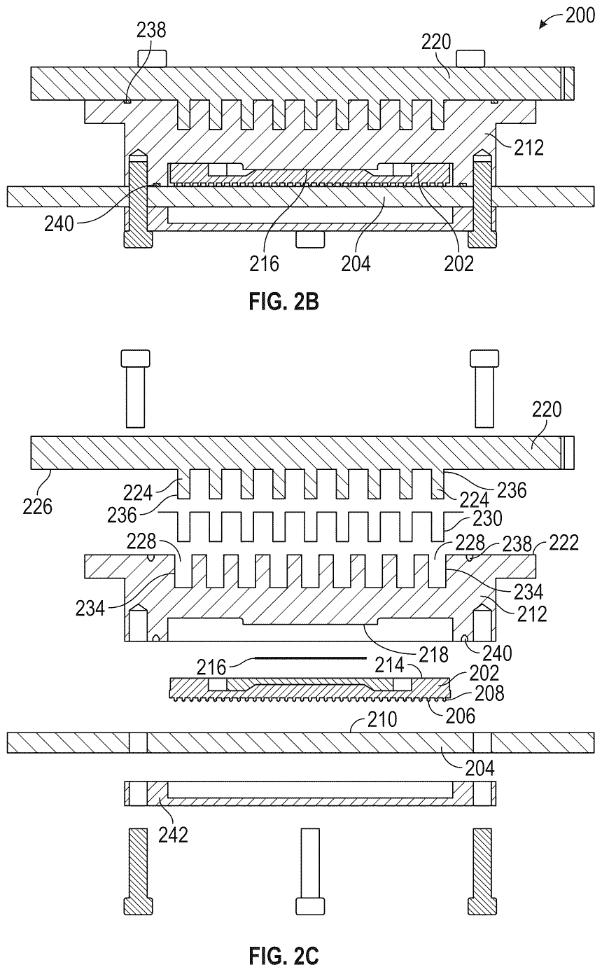

Now referring to FIG. 1, a spacecraft 100 is shown in which an assembly 200 (FIGS. 2A-2C) can be disposed that can include an electrical component 202. The assembly 200 can be configured to provide heat conduction and dissipation for the electrical component 202. The electrical component 202 can be mounted on a printed wiring board 204 at bottom side 206. The printed wiring board 204 can include a substrate that can support and connect electronic components, such as the electronic component 202, using conductive pathways that can be printed or etched onto a non-conductive substrate. The substrate of the printed wiring board 204 can be formed from phenolic paper, epoxy glass, polymide, or the like. In addition, the substrate of the printed wiring board 204 can be formed from a material providing any suitable mechanical strength and electrical insulation suitable for spacecraft applications.

The electronic component 202 can be an active component, a passive component, or specialized component. Examples of active components can include a transistor, a diode, an integrated circuit, a microprocessor, or an operational amplifier. Examples of passive components can include a resistor, a capacitor, an inductor, a transformer, or a potentiometer. Examples of a specialized component can include a Zener diode or a varicap diode. While active, passive, and specialized components are described herein, the electronic component 202 is not restricted to the components discussed herein. For example, the electronic component 202 can be an ideal diode controller, a light-to-frequency converter, an ultra-low voltage adjustable shunt regulator, or any type of computing processor.

The electronic component 202 can have a ball grid array 208 that contacts a first side 210 of printed wiring board 204. In order to attach the ball grid array 208 to the printed wiring board 204, the ball grid array 208 can be aligned with pads on the printed wiring board 204 and then attached to the printed wiring board 204 using stencil printing and solder paste. The formed assembly between the printed wiring board 204 and the ball grid array 208 can then be subjected to a reflow process where the printed wiring board 204 is subjected to a heating process.

The assembly 200 can have a heat sink 212 disposed on a top surface 214 of the electrical component 202. The heat sink 212 can dissipate heat away from the electrical component 202 in order to prevent overheating of the electrical component 202. The heat sink 212 can be formed of a material having high thermal conductivity and capable of drawing heat from the electrical component 202. Examples of materials that can be used to form the heat sink 212 can include copper, a copper composite, aluminum, stainless steel, albemet, aluminum, an aluminum composite, beryllium or a beryllium composite. or the like.

A TIM layer 216 can be disposed on the electrical component top surface 214 such that the TIM layer 216 contacts both the electrical component 202 at the electrical component top surface 214 and a bottom surface 218 of the heat sink 212. As such, the TIM layer 216 can form a thermal path between the electrical component 202 and the heat sink 212. The TIM layer 216 can be considered an electrical component TIM layer. Furthermore, the heat sink 212 can be formed from a material having a thermal conductivity that is higher than an overall thermal conductivity of the electrical component 202. Thus, heat from the electrical component 202 can be transferred to the heat sink 212 via the TIM layer 216.

The TIM layer 216 can be formed of a bond material that can provide thermal management. The TIM layer 216 can be a gap filler formed from a compound having silicone and fiberglass, a putty, a gel, or the like that is capable of bonding the electrical component 202 with the heat sink 212. Examples of the TIM layer 216 can include various materials available from Henkel™ AG & CO headquartered in Düsseldorf, Germany under the Bergquist™ line of products, such as the Bergquist™ Gap Pad TGP line of products, Bergquist™ TIC Gap Filler line of products, timtronics, or the like.

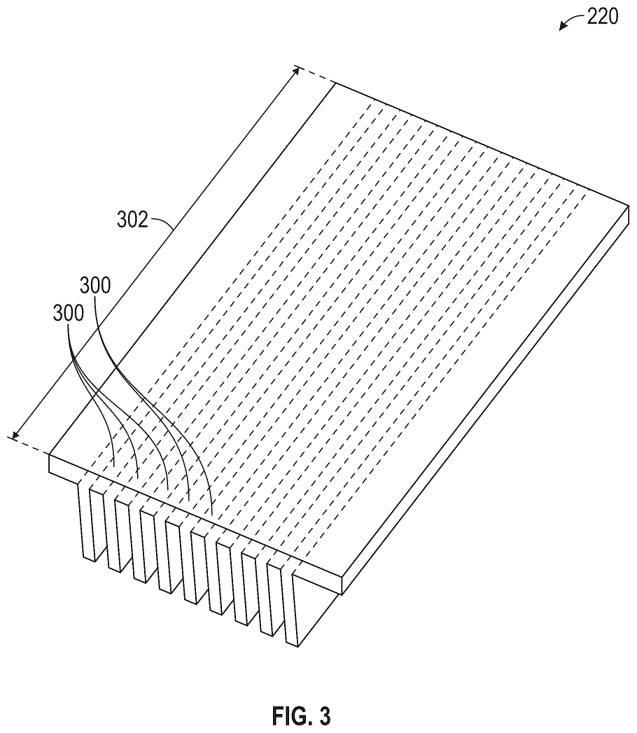

The assembly 200 can have a cover 220 disposed on the heat sink 216 at a top surface 222 of the heat sink 216. The cover 220 can define a plurality of cooling fins 224 that extend from a bottom surface 226 of the cover 220. As shown with reference to FIG. 3, the cooling fins 224 can define a pattern 300. In particular, the cooling fins 224 can run across a width/length 302 of the cover 220. Moreover, the cover 220 can include any number of cooling fins 224. The cover 220 along with the cooling fins 224 can be formed of any conductive material. Examples can include stainless steel, aluminum, ablemet, or any type of metal alloy capable of conducting heat.

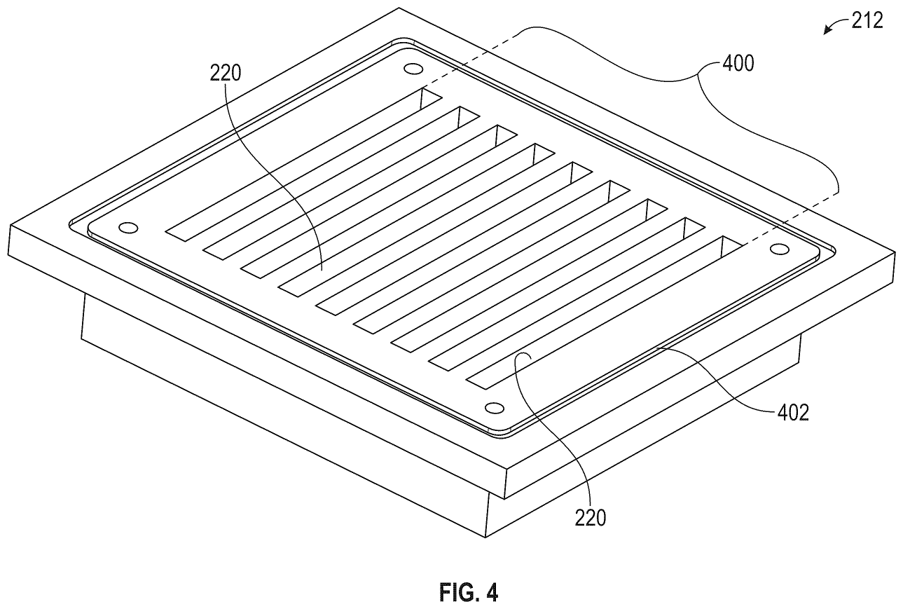

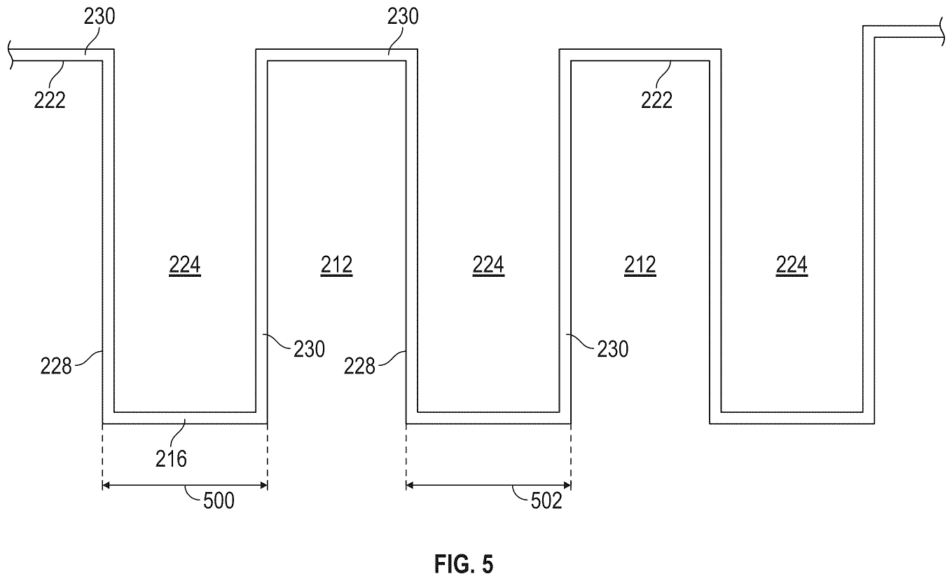

The heat sink 212 can include a plurality of cooling fin recesses 228 at a top surface 222 of the heat sink 216 as shown with reference to FIGS. 2B and 2C, 4, and 5. The cooling fin recesses 220 can have a pattern 400 (FIG. 4) that is complementary to the cooling fin pattern 300. Thus, as shown with reference to FIGS. 2B and 5, the cooling fins 224 can fit within the cooling fin recesses 228. In examples, the cooling fin recesses 228 can have a width 500 that is larger than a width 502 of the cooling fins 224. By virtue of the cooling fin recess width 500 being larger than the cooling fin width 502 and the cooling fin recess pattern 400 being complementary to the cooling fin pattern 300, the cooling fins 224 can fit within the cooling fin recesses 224.

A TIM layer 230 can be disposed between the heat sink 212 and the cover 220, as shown with reference to FIGS. 2C and 5. More specifically, the TIM layer 230 can be disposed within the cooling fin recesses 228 and between the heat sink top surface 222 and the cover bottom surface 226. Thus, the TIM layer 230 can form a thermal path between the heat sink 212 and the cover 220. Furthermore, a top surface 232 (FIG. 2A) of the cover 220 can be exposed. Thus, the cover top surface 232 can dissipate heat transferred to the cover 220 from the heat sink 216 via the TIM layer 230. The TIM layer 230 can be considered a heat sink TIM layer.

The TIM layer 230 can be formed from the same material as the TIM layer 216. In examples where the TIM layer 230 is formed from a gap filler, the TIM layer 230 can be formed as a pressure gasket within the cooling fin recesses 228. By virtue of being formed from a conductive material, the TIM layer 230 can form a thermal path between the heat sink 212 and the cover 220.

The assembly 200 can also include gaskets 238 and 240. The gasket 238 can function to seal the heat sink 212 with the cover 220. The gasket 238 can be disposed in a trough 402 (FIG. 4) that is disposed about a periphery of the heat sink 212. The gasket 240 can function to seal the heat sink 212 with printed wiring board 204. The heat sink 212 can include a trough about within which the gasket 240. Each of the gaskets 238 and 240 can be formed from a material conducive to sealingly engaging the heat sink 212 with the cover 220 and the PCB 204. Examples can include any type of rubber, rubber polymer, or any other type of polymer.

The assembly 200 can also have a bottom cover 242. In examples, the cover 220 can be a top cover for the assembly 200 such that the cover 220 in conjunction with the bottom cover 242 can form an enclosure for the assembly 200.

Examples can maximize a thermal conductive surface area between the heat sink 212 and the cover 220. In particular, the cooling fin recesses 228 can include sidewalls 234 and the cooling fins 224 can include sidewalls 236. The cooling fin recess sidewalls 234 and the cooling fin sidewalls 236 can multiply a surface area of the heat sink 212 that is in thermal contact with the cover 220 where the TIM layer 230 can form a thermal path between the cooling fin recess sidewalls 234 and the cooling fin sidewalls 236. By virtue of multiplying the thermal surface area, the ability of the assembly 200 to dissipate heat from the electrical component 202 is enhanced, thereby minimizing the heat dissipation problems of electrical components in outer space applications discussed above.

Moreover, if the assembly 200 requires reworking, the configuration of the heat sink 212 thermally interfacing with the cover via the TIM layer 230, the cooling fins 224, and the cooling fin recesses 228 allows for easy disassembly of the assembly 200. Furthermore, the number of cooling fins and complementary cooling fin recesses can be design specific. Thus, if a greater number of cooling fins and cooling fin recesses are required, the assembly 200 can be reworked to easily accommodate more cooling fins and cooling fin recesses to increase heat dissipation capacity. Moreover, the design of the cooling fins and the complementary cooling fin recesses discussed herein lend themselves to automated manufacturing, such as Computer Numerical Control manufacturing techniques and the like.

### Additional Examples

Example 1 is an assembly for providing heat conduction for an electrical component of a spacecraft, the assembly comprising: a printed wiring board, wherein: the electrical component has a first side and a second side, the electrical component being disposed on a surface of the printed wiring board at the electrical component first side; a first thermal interface material (TIM) disposed on the electrical component second side; a heat sink having a first side and a second side, the heat sink being disposed on the first TIM at the heat sink first side and opposite the electrical component, the first TIM being in thermal contact with the electrical component and the heat sink; a cover disposed on the heat sink second side, the cover defining a plurality of cooling fins having a cooling fin pattern, the heat sink including a plurality of cooling fin recesses, the plurality of cooling fin recesses defining a cooling fin recess pattern that is complementary to the cooling fin pattern; and a second TIM disposed within the plurality of cooling fin recesses and being in contact with the heat sink and the cover via the plurality of cooling fins and the plurality of cooling fin recesses.

In Example 2, the subject matter of Example 1 includes, wherein the first TIM and the second TIM are each a gap filler comprising silicone.

In Example 3, the subject matter of Example 2 includes, wherein the gap filler of the second TIM is formed as a gasket within the cooling fin recesses.

In Example 4, the subject matter of Examples 1-3 includes, wherein each of the first TIM and the second TIM are a putty.

In Example 5, the subject matter of Examples 1-4 includes, wherein the heat sink is formed from copper, a copper composite, aluminum, an aluminum composite, beryllium or a beryllium composite.

In Example 6, the subject matter of Examples 1-5 includes, wherein the printed wiring board includes a first side and a second side and the electrical component is at the printed wiring board first side.

In Example 7, the subject matter of Example 6 includes, wherein the cover forms a top enclosure and the assembly further comprises a bottom enclosure disposed at a the printed wiring board second side.

Example 8 is an assembly for providing heat conduction for an electrical component of a spacecraft, the assembly comprising: a first thermal interface material (TIM) disposed on the electrical component; a heat sink having a first side and a second side, the heat sink being disposed on the first TIM at the heat sink first side and opposite the electrical component, the first TIM being in thermal contact with the electrical component and the heat sink; a cover disposed on the heat sink second side, the cover defining a plurality of cooling fins having a cooling fin pattern, the heat sink including a plurality of cooling fin recesses, the plurality of cooling fin recesses defining a cooling fin recess pattern that is complementary to the cooling fin pattern; and a second TIM disposed within the plurality of cooling fin recesses and being in contact with the heat sink and the cover via the plurality of cooling fins and the plurality of cooling fin recesses.

In Example 9, the subject matter of Example 8 includes, wherein the electrical component has a first side and a second side and the assembly further comprises a printed wiring board disposed at the electrical component first side where the first TIM is disposed at the electrical component second side.

In Example 10, the subject matter of Examples 8-9 includes, wherein the first TIM and the second TIM are each a gap filler comprising silicone and fiberglass.

In Example 11, the subject matter of Example 10 includes, wherein the gap filler of the second TIM is formed as a pressure gasket within the plurality of cooling fin recesses.

In Example 12, the subject matter of Examples 8-11 includes, wherein each of the first TIM and the second TIM are a putty or a gel.

In Example 13, the subject matter of Examples 8-12 includes, wherein the heat sink is formed from copper, a copper composite, aluminum, an aluminum composite, beryllium or a beryllium composite.

In Example 14, the subject matter of Examples 8-13 includes, the assembly further comprising a printed wiring board, wherein the printed wiring board includes a first side and a second side and the electrical component is at the printed wiring board first side.

In Example 15, the subject matter of Example 14 includes, wherein the cover forms a top enclosure and the assembly further comprises a bottom enclosure disposed at a the printed wiring board second side.

Example 16 is an assembly for providing heat conduction for an electrical component of a spacecraft, the assembly comprising: a heat sink having a first side and a second side, the heat sink being disposed on the electrical component at the heat sink first side; a cover disposed on the heat sink second side, the cover defining a plurality of cooling fins having a cooling fin pattern, the heat sink including a plurality of cooling fin recesses, the plurality of cooling fin recesses defining a cooling fin recess pattern that is complementary to the cooling fin pattern; and a heat sink thermal interface material (TIM) disposed within the plurality of cooling fin recesses and being in contact with the heat sink and the cover via the plurality of cooling fins and the plurality of cooling fin recesses.

In Example 17, the subject matter of Example 16 includes, the assembly further comprising an electrical component TIM disposed on the electrical component, wherein the heat sink is disposed on the electrical component TIM and the electrical component TIM is in thermal contact with the electrical component and the heat sink.

In Example 18, the subject matter of Example 17 includes, wherein the electrical component has a first side and a second side where the electrical component TIM is disposed at the electrical component first side and the assembly further comprises a printed wiring board disposed at the electrical component first side where the electrical component TIM is disposed at the electrical component second side.

In Example 19, the subject matter of Examples 16-18 includes, wherein the first TIM and the second TIM are each a gap filler comprising silicone and fiberglass and the gap filler of the second TIM is formed as a pressure gasket within the plurality of cooling fin recesses.

In Example 20, the subject matter of Examples 16-19 includes, the assembly further comprising a printed wiring board, wherein: the printed wiring board includes a first side and a second side and the electrical component is at the printed wiring board first side; and the cover forms a top enclosure and the assembly further comprises a bottom enclosure disposed at a the printed wiring board second side.

Example 21 is an apparatus comprising means to implement of any of Examples 1-20.

Example 22 is a method to implement of any of Examples 1-20.

Although teachings have been described with reference to specific example teachings, it will be evident that various modifications and changes may be made to these teachings without departing from the broader spirit and scope of the teachings. Accordingly, the specification and drawings are to be regarded in an illustrative rather than a restrictive sense. The accompanying drawings that form a part hereof, show by way of illustration, and not of limitation, specific teachings in which the subject matter may be practiced. The teachings illustrated are described in sufficient detail to enable those skilled in the art to practice the teachings disclosed herein. Other teachings may be utilized and derived therefrom, such that structural and logical substitutions and changes may be made without departing from the scope of this disclosure. This Detailed Description, therefore, is not to be taken in a limiting sense, and the scope of various teachings is defined only by the appended claims, along with the full range of equivalents to which such claims are entitled.

What is claimed is:

1. An assembly for providing heat conduction for an electrical component of a spacecraft, the assembly comprising:
a printed wiring board, wherein:
the electrical component has a first side and a second side, the electrical component being disposed on a surface of the printed wiring board at the electrical component first side;
a first thermal interface material (TIM) disposed on the electrical component second side;
a heat sink having a first side and a second side, the heat sink being disposed on the first TIM at the heat sink first side and opposite the electrical component, the first TIM being in thermal contact with the electrical component and the heat sink;
a cover disposed on the heat sink second side, the cover defining a plurality of cooling fins having a cooling fin pattern, the heat sink including a plurality of cooling fin recesses, the plurality of cooling fin recesses defining a cooling fin recess pattern that is complementary to the cooling fin pattern; and
a second TIM disposed within the plurality of cooling fin recesses and being in contact with the heat sink and the cover via the plurality of cooling fins and the plurality of cooling fin recesses.

2. The assembly of claim 1, wherein the first TIM and the second TIM are each a gap filler comprising silicone.

3. The assembly of claim 2, wherein the gap filler of the second TIM is formed as a gasket within the cooling fin recesses.

4. The assembly of claim 1, wherein each of the first TIM and the second TIM are a putty.

5. The assembly of claim 1, wherein the heat sink is formed from copper, a copper composite, aluminum, an aluminum composite, beryllium or a beryllium composite.

6. The assembly of claim 1, wherein the printed wiring board includes a first side and a second side and the electrical component is at the printed wiring board first side.

7. The assembly of claim 6, wherein the cover forms a top enclosure and the assembly further comprises a bottom enclosure disposed at a the printed wiring board second side.

8. An assembly for providing heat conduction for an electrical component of a spacecraft, the assembly comprising:
a first thermal interface material (TIM) disposed on the electrical component;
a heat sink having a first side and a second side, the heat sink being disposed on the first TIM at the heat sink first side and opposite the electrical component, the first TIM being in thermal contact with the electrical component and the heat sink;
a cover disposed on the heat sink second side, the cover defining a plurality of cooling fins having a cooling fin pattern, the heat sink including a plurality of cooling fin recesses, the plurality of cooling fin recesses defining a cooling fin recess pattern that is complementary to the cooling fin pattern; and
a second TIM disposed within the plurality of cooling fin recesses and being in contact with the heat sink and the cover via the plurality of cooling fins and the plurality of cooling fin recesses.

9. The assembly of claim 8, wherein the electrical component has a first side and a second side and the assembly further comprises a printed wiring board disposed at the electrical component first side where the first TIM is disposed at the electrical component second side.

10. The assembly of claim 8, wherein the first TIM and the second TIM are each a gap filler comprising silicone and fiberglass.

11. The assembly of claim 10, wherein the gap filler of the second TIM is formed as a pressure gasket within the plurality of cooling fin recesses.

12. The assembly of claim 8, wherein each of the first TIM and the second TIM are a putty or a gel.

13. The assembly of claim 8, wherein the heat sink is formed from copper, a copper composite, aluminum, an aluminum composite, beryllium or a beryllium composite.

14. The assembly of claim 8, the assembly further comprising a printed wiring board, wherein the printed wiring board includes a first side and a second side and the electrical component is at the printed wiring board first side.

15. The assembly of claim 14, wherein the cover forms a top enclosure and the assembly further comprises a bottom enclosure disposed at a the printed wiring board second side.

16. An assembly for providing heat conduction for an electrical component of a spacecraft, the assembly comprising:
a heat sink having a first side and a second side, the heat sink being disposed on the electrical component at the heat sink first side;
a cover disposed on the heat sink second side, the cover defining a plurality of cooling fins having a cooling fin pattern, the heat sink including a plurality of cooling fin recesses, the plurality of cooling fin recesses defining a cooling fin recess pattern that is complementary to the cooling fin pattern; and
a heat sink thermal interface material (TIM) disposed within the plurality of cooling fin recesses and being in contact with the heat sink and the cover via the plurality of cooling fins and the plurality of cooling fin recesses.

17. The assembly of claim 16, the assembly further comprising an electrical component TIM disposed on the electrical component, wherein the heat sink is disposed on the electrical component TIM and the electrical component TIM is in thermal contact with the electrical component and the heat sink.

18. The assembly of claim 17, wherein the electrical component has a first side and a second side where the electrical component TIM is disposed at the electrical component first side and the assembly further comprises a printed wiring board disposed at the electrical component first side where the electrical component TIM is disposed at the electrical component second side.

19. The assembly of claim 16, wherein the first TIM and the second TIM are each a gap filler comprising silicone and fiberglass and the gap filler of the second TIM is formed as a pressure gasket within the plurality of cooling fin recesses.

20. The assembly of claim 16, the assembly further comprising a printed wiring board, wherein:
the printed wiring board includes a first side and a second side and the electrical component is at the printed wiring board first side; and
the cover forms a top enclosure and the assembly further comprises a bottom enclosure disposed at a the printed wiring board second side.
